(19) United States
(12) Patent Application Publication
(10) Pub. No.: US 2008/0288193 A1
(43) Pub. Date: Nov. 20, 2008

(54) Techniques for Analyzing Data Center Energy Utilization Practices

(75) Inventors: Alan Claassen, Fremont, CA (US); Hendrik F. Hamann, Yorktown Heights, NY (US); Madhusudan K. Iyengar, Woodstock, NY (US); Martin Patrick O'Boyle, Cream Ridge, NJ (US); Michael Alan Schappert, Wappingers Falls, NY (US); Theodore Gerard van Kessel, Millbrook, NY (US)

Correspondence Address: MICHAEL J. CHANG, LLC, 84 SUMMIT AVENUE, MILFORD, CT, 06460, US

(73) Assignee: International Business Machines Corporation, Armonk, NY (US)

(21) Appl. No.: 11/750,325

(22) Filed: May 17, 2007

(51) Int. Cl. G01R 21/00

(52) U.S. Cl. 702/61

(57) ABSTRACT

Techniques for improving on data center best practices are provided. In one aspect, an exemplary methodology for analyzing energy efficiency of a data center having a raised-floor cooling system with at least one air conditioning unit is provided. The method comprises the following steps. An initial assessment is made of the energy efficiency of the data center based on one or more power consumption parameters of the data center. Physical parameter data obtained from one or more positions in the data center are compiled into one or more metrics, if the initial assessment indicates that the data center is energy inefficient. Recommendations are made to increase the energy efficiency of the data center based on one or more of the metrics.

### CROSS-REFERENCE TO RELATED APPLICATIONS

This application is related to the commonly owned U.S. application Ser. No. ______, entitled “Techniques for Data Center Cooling,” designated as Attorney Reference No. YOR920070177US1, filed herewith on the same day of May 17, 2007, the contents of which are incorporated herein by reference as fully set forth herein.

### FIELD OF THE INVENTION

The present invention relates to data centers, and more particularly, to data center best practices including techniques to improve thermal environment and energy efficiency of the data center.

### BACKGROUND OF THE INVENTION

Computer equipment is continually evolving to operate at higher power levels. Increasing power levels pose challenges with regard to thermal management. For example, many data centers now employ individual racks of blade servers that can develop 20,000 watts, or more, worth of heat load. Typically, the servers are air cooled and, in most cases, the data center air conditioning infrastructure is not designed to handle the thermal load.

Companies looking to expand their data center capabilities are thus faced with a dilemma, either incur the substantial cost of building a new data center system with increased cooling capacity, or limit the expansion of their data center to remain within the limits of their current cooling system. Neither option is desirable.

Further, a recent study from the Lawrence Berkeley National Laboratory has reported that, in 2005, server-driven power usage amounted to 1.2 percent (i.e., 5,000 megawatts (MW)) and 0.8 percent (i.e., 14,000 MW) of the total United States and world energy consumption, respectively. See, J. G. Koomey, Estimating Total Power Consumption By Servers In The U.S. and The World, A report by the Lawrence Berkeley National Laboratory, February (2007) (hereinafter “Koomey”). According to Koomey, the cost of this 2005 server-driven energy usage was $2.7 billion and $7.2 billion for the United States and the world, respectively. The study also reported a doubling of server-related electricity consumption between the years 2000 and 2005, with an anticipated 15 percent per year growth rate.

Thus, techniques for understanding and improving on the energy efficiency of data centers would be desirable, both from the standpoint of improving the efficiency of existing data center infrastructures, as well as from a cost and sustainability standpoint.

### SUMMARY OF THE INVENTION

The present invention provides techniques for improving on data center best practices. In one aspect of the invention, an exemplary methodology for analyzing energy efficiency of a data center having a raised-floor cooling system with at least one air conditioning unit is provided. The method comprises the following steps. An initial assessment is made of the energy efficiency of the data center based on one or more power consumption parameters of the data center. Physical parameter data obtained from one or more positions in the data center are compiled into one or more metrics, if the initial assessment indicates that the data center is energy inefficient. Recommendations are made to increase the energy efficiency of the data center based on one or more of the metrics.

A more complete understanding of the present invention, as well as further features and advantages of the present invention, will be obtained by reference to the following detailed description and drawings.

### BRIEF DESCRIPTION OF THE DRAWINGS

FIG. 1 is a diagram illustrating an exemplary methodology for analyzing energy efficiency of a data center according to an embodiment of the present invention;

FIG. 2 is a diagram illustrating electricity flow and energy use in an exemplary data center according to an embodiment of the present invention;

FIG. 3 is a graph illustrating energy efficiency for various data centers according to an embodiment of the present invention;

FIG. 4 is a graph illustrating power consumption in a data center according to an embodiment of the present invention;

FIG. 5 is a diagram illustrating an exemplary heat rejection path via a cooling infrastructure in a data center according to an embodiment of the present invention;

FIG. 6 is a diagram illustrating an exemplary raised-floor cooling system in a data center according to an embodiment of the present invention;

FIG. 7 is a diagram illustrating how best practices impact transport and thermodynamic factors of cooling power consumption in a data center according to an embodiment of the present invention;

FIG. 8 is a graph illustrating a relationship between refrigeration chiller power consumption and part load factor according to an embodiment of the present invention;

FIG. 9 is a graph illustrating a relationship between energy efficiency of a refrigeration chiller and an increase in a chilled water temperature set point according to an embodiment of the present invention;

FIG. 10 is a graph illustrating air conditioning unit blower power consumption according to an embodiment of the present invention:

FIG. 11 is an exemplary three-dimensional thermal image of a data center generated using mobile measurement technology (MMT) according to an embodiment of the present invention;

FIG. 12 is a table illustrating metrics according to an embodiment of the present invention;

FIG. 13 is a diagram illustrating an exemplary MMT scan for pinpointing hotspots within a data center according to an embodiment of the present invention;

FIG. 14 is a diagram illustrating an exemplary vertical temperature map according to an embodiment of the present invention;

FIG. 15 is a table illustrating metrics, key actions and expected energy savings according to an embodiment of the present invention; and

FIG. 16 is a diagram illustrating an exemplary system for analyzing energy efficiency of a data center according to an embodiment of the present invention.

### DETAILED DESCRIPTION OF PREFERRED EMBODIMENTS

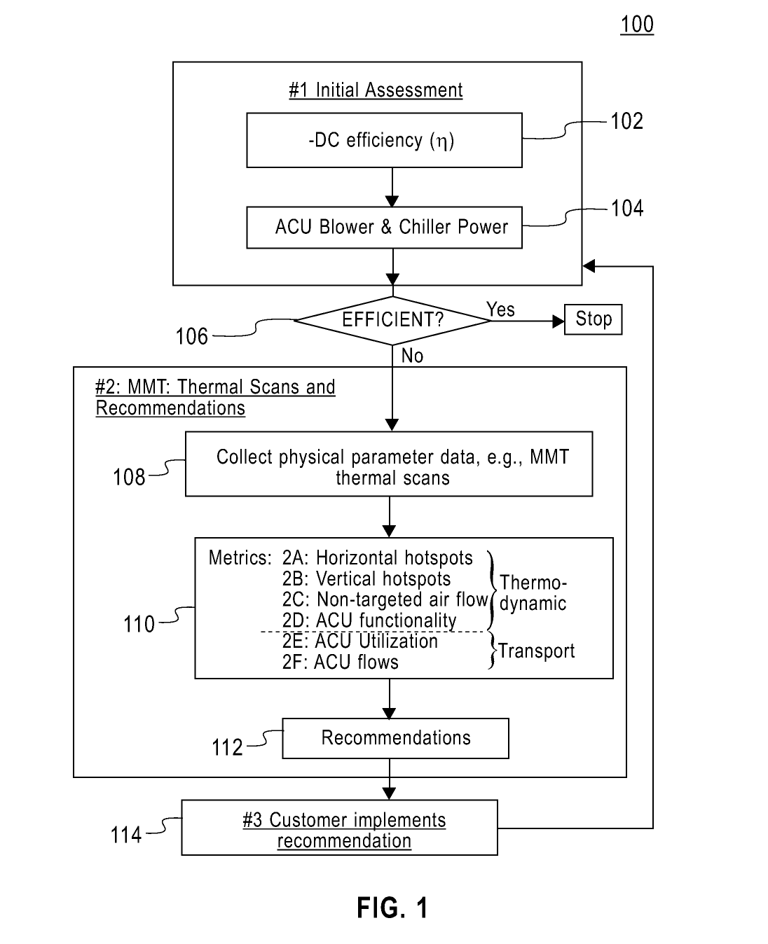

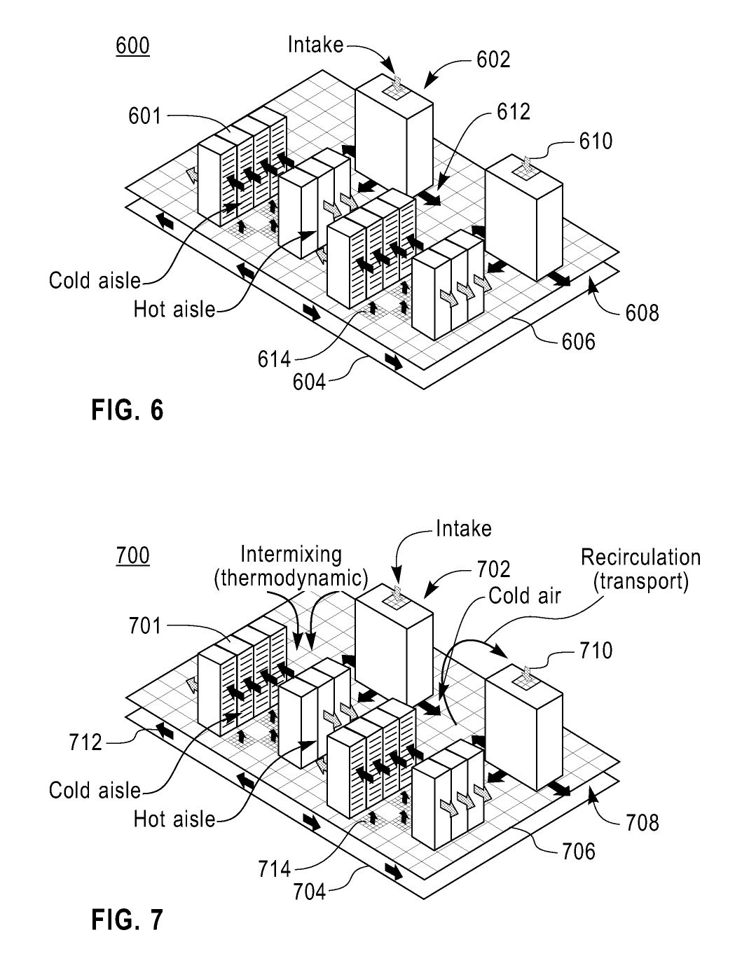

FIG. 1 is a diagram illustrating exemplary methodology 100 for analyzing energy efficiency of an active, running, data center. According to an exemplary embodiment, the data center is cooled by a raised-floor cooling system having air conditioning units (ACUs) associated therewith. Data centers with raised-floor cooling systems are described, for example, in conjunction with the description of FIGS. 6 and 7, below.

A goal of methodology 100 is to improve energy (and space) efficiency of the data center by improving the data center cooling system infrastructure. As will be described in detail below, these improvements can occur in one or more of a thermodynamic and a transport aspect of the cooling system.

Steps 102 and 104 make up an initial assessment phase of methodology 100. Steps 108-112 make up a data gathering, analysis and recommendation phase of methodology 100. Step 114 makes up an implementation of best practices phase of methodology 100.

In step 102, an initial assessment is made of the energy efficiency (it) of the data center. This initial assessment can be based on readily obtainable power consumption parameters of the data center. By way of example only, in one embodiment, the initial assessment of the energy efficiency of the data center is based on a ratio of information technology (IT) power consumption (e.g., power consumed by IT and related equipment, such as uninterruptible power supplies (UPSs), power distribution units (PDUs), cabling and switches) to overall data center power consumption (which includes, in addition to IT power consumption, power consumption by a secondary support infrastructure, including, e.g., cooling system components, data center lighting, fire protection, security, generator and switchgear). For example, a definition of energy efficiency of data center (η) that can be used in accordance with the present teachings, is η=Power for IT (P_{IT})/Power for data center (P_{DC}). See, for example, Green Grid Metrics—Describing Data Center Power Efficiency, Technical Committee White Paper by the Green Grid Industry Consortium, Feb. 20, 2007), the disclosure of which is incorporated by reference herein. The data center overall power consumption is usually obtainable from building monitoring systems or from the utility company, and the IT power consumption can be measured directly at one or more of the PDUs present throughout the data center.

As will be described in detail below. to cool the data center the ACUs employ chilled water received from a refrigeration chiller plant, i.e., via a refrigeration chiller. To help assess energy efficiency and energy savings, in step 104., an estimation is made of ACU power consumption and refrigeration chiller power consumption, i.e., P_{ACU} and P_{chiller}. As indicated above, and as will be described in detail below, the ACU power consumption is associated with a transport term of the cooling infrastructure, and the refrigeration chiller power consumption is associated with a thermodynamic term of the cooling infrastructure. The present techniques will address, in part, reducing P_{ACU} and P_{chiller}. Thus, according to an exemplary embodiment, the initial assessment of P_{ACU} and P_{chiller} can be later used, i.e., once methodology 100 is completed, to ascertain whether P_{ACU} and P_{chiller} have been reduced.

In step 106, based on the initial assessment of the energy efficiency of the data center made in step 102, above, a determination is then made as to whether the data center is energy efficient or not, e.g., based on whether the assessed level of energy efficiency is satisfactory or not. As will be described, for example, in conjunction with the description of FIG. 3, below, a large amount of variation in energy efficiency exists amongst different data centers, which indicates that significant energy-saving opportunities exist. By way of example only, data centers having an efficiency (η) of less than about 0.75, i.e., between about 0.25 and about 0.75, can be considered inefficient. It is to be understood however, that the efficiency of a given data center can depend on factors, including, but not limited to, geography, country and weather. Therefore, a particular efficiency value might be considered to be within an acceptable range in one location, but not acceptable in another location.

When it is determined that the data center is energy efficient, e.g., when η is satisfactory, no further analysis is needed. However, when it is determined that the data center is energy inefficient, e.g., η is not satisfactory, then the analysis continues.

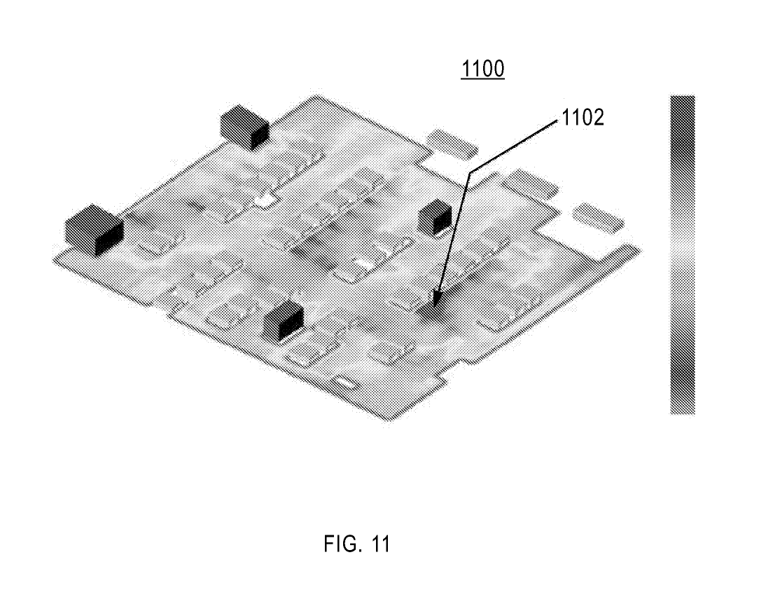

In step 108, physical parameter data are collected from the data center. As will be described in detail below, the physical parameter data can include, but are not limited to, temperature, humidity and air flow data for a variety of positions within the data center. According to an exemplary embodiment, the temperature and humidity data are collected front the data center using mobile measurement technology (MMT) thermal scans of the data center. The MMT scans result in detailed three-dimensional temperature images of the data center which can be used as a service to help customers implement recommendations and solutions in their specific environment. MMT is described in detail, for example, in conjunction with the description of FIG. 11, below. According to an exemplary embodiment, air flow data from the data center is obtained using one or more of a velometer flow hood, a vane anemometer or The Velgrid (manufactured by Shortridge Instruments, Inc., Scottsdale, Ariz.).

In step 110, the physical parameter data obtained from the data center are compiled into a number of metrics. As will be described in detail below. according to a preferred embodiment, the physical parameter data are compiled into at least one of six key metrics, namely a horizontal hotspots metric (i.e. an air inlet temperature variations metric), a vertical hotspots metric, a non-targeted air flow metric, a sub-floor plenum hotspots metric, an ACU utilization metric and/or an ACU air flow metric. The first four metrics, i.e., the horizontal hotspots metric, the vertical hotspots metric, the non-targeted air flow metric and the sub-plenum hotspots metric are related to, and affect, thermodynamic terms of energy savings. The last two metrics, i.e., the ACU utilization metric and the ACU air flow metric are related to, and affect, transport terms of energy savings. Since the metrics effectively quantify, i.e. gauge the extent of, hotspots, non-targeted air flow (thermodynamic) and ACU utilization/air flow (transport) in the data center, they can be used to give customers a tool to understand their data center efficiency and a tract-able way to save energy based on low-cost best practices.

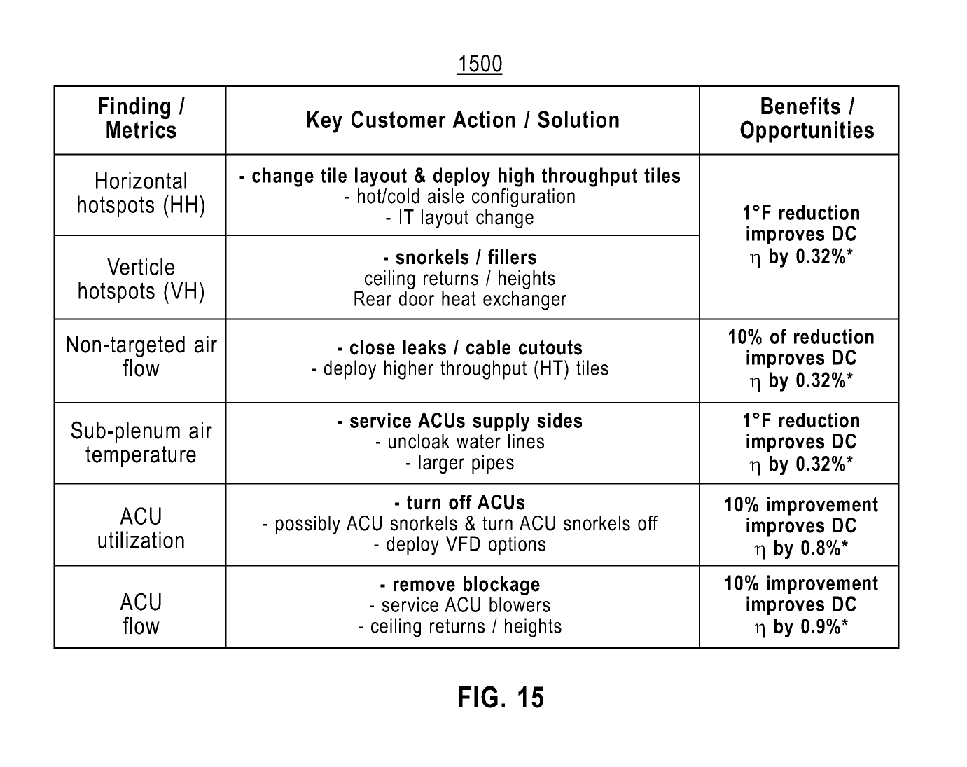

In step 112, based on the findings from compiling the physical parameter data into the metrics in step 110, above, recommendations can be made regarding best practices to increase the energy efficiency of the data center (energy savings). As will be described, for example, in conjunction with the description of FIG. 15, below, these recommendations can include. but are not limited to, placement and/or number of perforated floor tiles and placement and/or orientation of IT equipment and ducting to optimize air flow, which are low-cost solutions a customer can easily implement.

In step 114, customers can implement changes in their data centers based on the recommendations made in step 112, above. After the changes are implemented, one or more of the steps of methodology 100 can be repeated to determine whether the energy efficiency of the data center has improved. By way of example only, one or more of the recommendations are implemented, a reassessment of the energy efficiency of the data center can be performed, and compared with the initial assessment (step 103) to ascertain energy savings.

It is widely acknowledged that the energy efficiency of a data center is primarily determined by the extent of the implementation of best practices. In particular, data center cooling power consumption, which is a significant fraction of the total data center power, is largely governed by the IT equipment layout, chilled air flow control and many other factors.

A new service solution is described herein, which exploits the superiority of fast and massive parallel data collection using the MMT to drive towards quantitative measurement driven data center best practices implementation. Parallel data collection indicates that data is being collected using several sensors in different location at the same time. The MMT (described below) has more than 100 temperature sensors, which collect spatial temperature data simultaneously. The data center is thermally characterized via three dimensional temperature maps and detailed flow parameters which are used to calculate six key metrics (horizontal and vertical hotspots, non-targeted air flow, plenum air temperature variations of the air conditioning unit (ACU) discharge temperatures and flow blockage. The metrics provide quantitative insights regarding the sources of energy efficiencies. Most importantly the metrics have been chosen such that each metric corresponds to a clear set of solutions, which are readily available to the customer. By improving on each of these metrics, the customer can clearly gauge, systematically, the progress towards a more energy efficient data center.

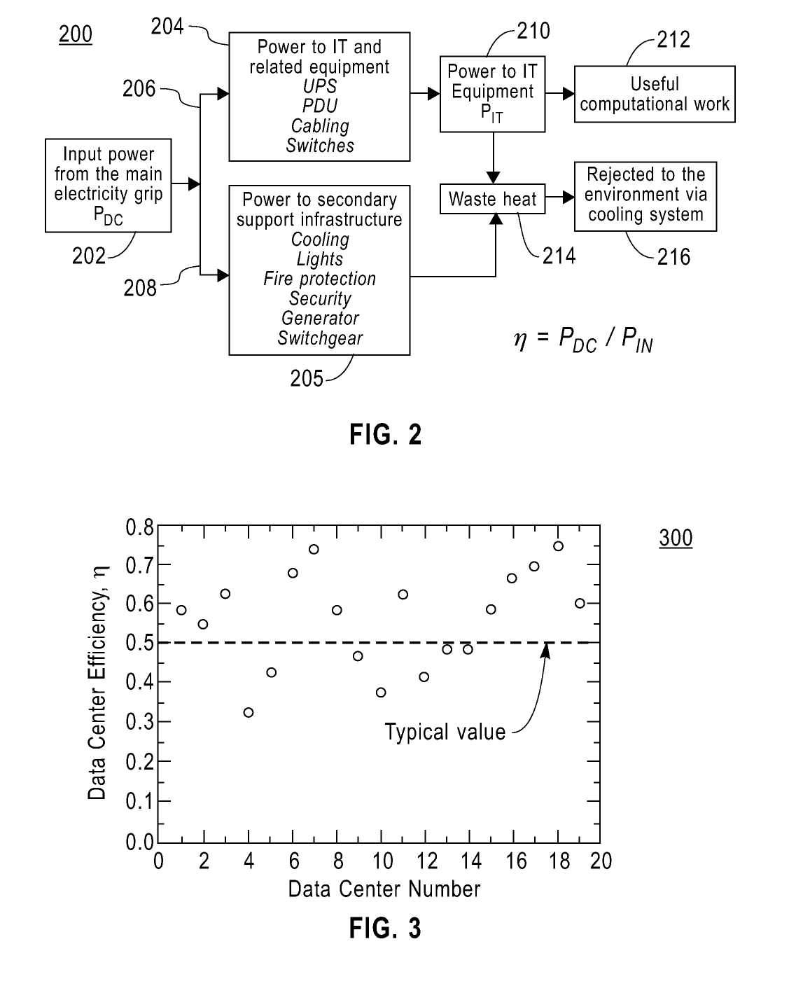

As described above, in step 102 an initial assessment of the energy efficiency of the data center is made. FIG. 2 is a diagram illustrating electricity flow and energy use in exemplary data center 200. Namely, FIG. 2 depicts the flow of input electricity 202 from a main grid to various parts of data center 200, including IT and related equipment.

As shown in FIG. 2, the total power for the data center (P_{DC}) is split into path 206, for power 204 for the IT and related equipment (e.g., UPS, PDUs, cabling and switches), and path 208, for power 205 for support of the IT (e.g., secondary support infrastructure, such as cooling, lights, fire protection, security. generator and switchgear). The IT power path 204 is further conditioned, via the UPS, which is further distributed via the PDUs as power 210 to the IT equipment for computational work 212. All the electrical power is converted ultimately (according to the 2nd law of thermodynamics) into heat, i.e., waste heat 214, which is then rejected to the environment using cooling system 216.

FIG. 3 is a graph 300 illustrating energy efficiencies for 19 data centers. Graph 300 demonstrates that there are enormous variations in energy efficiency between different data centers, which shows that potentially significant energy saving opportunities exist. See, W. Tschudi, Best Practices Identified Through Benchmarking Data Centers, presentation at the ASHRAE Summer Conference, Quebec City, Canada, June (2006), the disclosure of which is incorporated by reference herein.

While most data center managers today have some generic knowledge about the fundamentals of data center best practices, it is a very different challenge to relate this generic knowledge to the context of their specific environment, as every data center is unique. For a summary of best practices, see, for example, High Performance Data Centers—A Design Guidelines Sourcebook, Pacific Gas and Electric Company Report, Developed by Rumsey Eng. & Lawrence Berkeley National Labs (2006), R. Schmidt, and M. Iyengar, Best Practices for Data Center Thermal and Energy Management—Review of Literature—. Proceedings of the ASHRAE Winter Meeting in Chicago, Paper DA-07-022 (2006) and C. Kurkjian and J. Glass, Air-Conditioning Design for Data Centers—Accommodating Current Loads and Planning for the Future, ASHRAE Transactions, Vol. 111, Part 2. Paper number DE-05-11-1 (2005), the disclosures of which arc incorporated by reference herein.

Thus, it remains an ongoing challenge for customers to implement these best practices in their specific environment. Quite often data center managers are confused and end up with non-optimum solutions for their environment. It is believed that by providing detailed, measurable metrics for data center best practices and by helping customers to implement these solutions in their specific environment, significant amounts of energy can be saved.

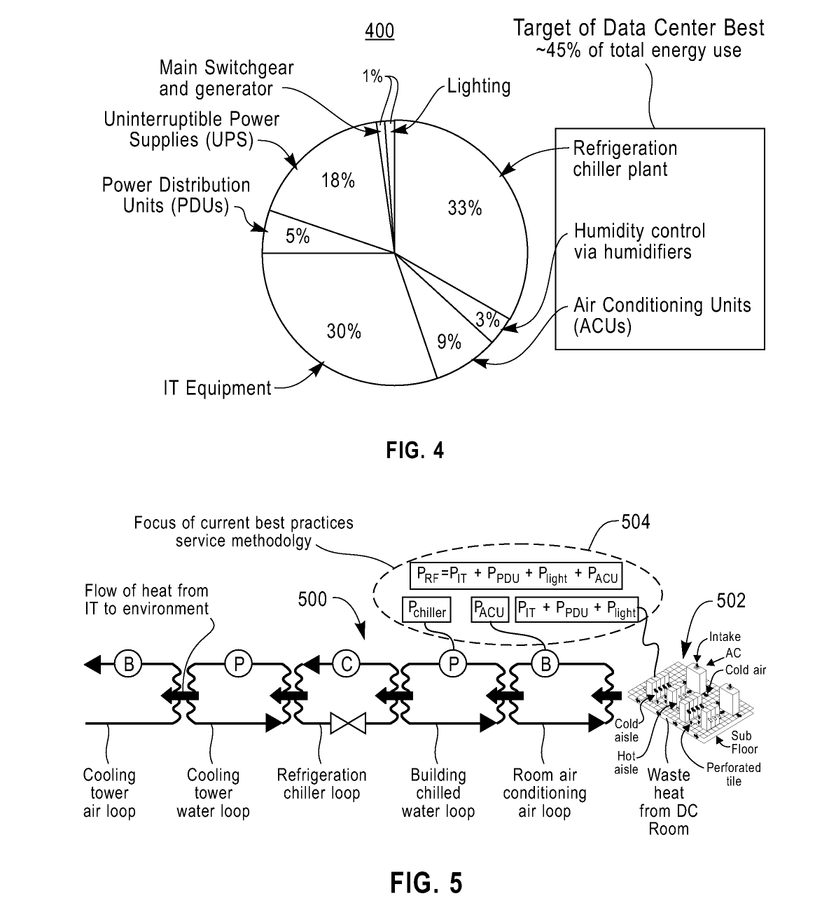

FIG. 4 is a graph 400 illustrating power consumption in a data center. The particular data center modeled in FIG. 4 is 30 percent efficient, with about 45 percent of total power for the data center (P_{DC}) being spent on a cooling infrastructure, e.g., including, but not limited to, a refrigeration chiller plant, humidifiers (for humidity control) and ACUs (also known as computer room air conditioning units (CRACs). Cooling infrastructures are described in further detail below.

An opportunity to improve energy efficiency of the data center lies in the discovery that the amount of power spent on the cooling infrastructure is governed by the energy utilization practices employed, i.e., the degree to which cooled air is efficiently and adequately distributed to a point of use. For a discussion of data center energy consumption, see, for example, Neil Rasmussen, Electrical Efficiency Modeling of Data Centers. White paper published by the American Power Conversion. Document no. 113, version 1 (2006), the disclosure of which is incorporated by reference herein.

FIG. 5 is a diagram illustrating heat rejection path 500 through a cooling infrastructure in a data center 502. Namely, heat rejection path 500 shows electrical heat energy dissipated by the IT equipment being carried away by successive thermally coupled cooling loops. Each coolant loop consumes energy, either due to pumping work or to compression work. In FIG. 5, a circled letter “P” indicates a cooling loop involving a water pump, a circled letter “C” indicates a cooling loop involving a compressor and a circled letter “B” indicates a cooling loop involving an air blower.

The cooling infrastructure in data center 502 is made up of a refrigeration chiller plant (which includes a cooling tower, cooling tower pumps and blowers, building chilled water pumps and a refrigeration chiller) and ACUs. Cooling infrastructure components are described in further detail below. As shown in FIG. 5, heat rejection path 500 through the cooling infrastructure involves a refrigeration chiller loop through the refrigeration chiller, a building chilled water loop through the building chilled water pumps and a data center air conditioning air loop through the ACUs. Caption 504 indicates the focus of the data center best practices of the present invention.

All of the power supplied to the raised floor (P_{RF}) is consumed by IT equipment and the supporting infrastructures (e.g., PDUs and ACUs) and is released into the surrounding environment as heat, which places an enormous burden on a cooling infrastructure, i.e., cooling system. As used herein, P_{RF} refers to the electrical power supplied to run the IT equipment, lighting the ACUs and the PDUs. Namely, P_{RF} is the power to the raised-floor, which includes power to IT, lighting, ACU, and PDUs. By comparison, P_{DC} is the total data center power, which includes the P_{RF} and also the equipment outside the raised floor room, e.g. the chiller, the cooling tower fans and pumps and the building chilled water pumps. Existing cooling technologies typically utilize air to carry the heat away from the chip, and reject to the ambient environment. This ambient environment in a typical data center is an air conditioned room, a small section of which is depicted in FIG. 6.

FIG. 6 is a diagram illustrating data center 600 having IT equipment racks 601 and a raised-floor cooling system with ACUs 602 that take hot air in (typically from above) and exhaust cooled air into a sub-floor plenum below. Hot air flow through data center 600 is indicated by light arrows 610 and cooled air flow through data center 600 is indicated by dark arrows 612.

In FIG. 6. the IT equipment racks 601 use front-to-back cooling and are located on raised-floor 606 with sub-floor 604 beneath. Namely, according to this scheme, cooled air is drawn in through a front of each rack and warm air is exhausted out from a rear of each rack. The cooled air drawn into the front of the rack is supplied to air inlets of each IT equipment component therein. Space between raised floor 606 and sub-floor 604 defines the sub-floor plenum 608. The sub-floor plenum 608 serves as a conduit to transport, e.g., cooled air from the ACUs 602 to the racks. In a properly-organized data center (such as data center 600), the IT equipment racks 601 are arranged in a hot aisle—cold aisle configuration, i.e. having air inlets and exhaust outlets in alternating directions. Namely, cooled air is blown through perforated floor tiles 614 in raised-floor 606, from the sub-floor plenum 608 into the cold aisles. The cooled air is then drawn into the IT equipment racks 601, via the air inlets, on an air inlet side of the racks and dumped, via the exhaust outlets. on an exhaust outlet side of the racks and into the hot aisles.

The ACUs typically receive chilled water from a refrigeration chiller plant (not shown). A refrigeration chiller plant is described in detail below. Each ACU typically comprises a blower motor to circulate air through the ACU and to blow cooled air, e.g., into the sub-floor plenum. As such, in most data centers, the ACUs are simple heat exchangers mainly consuming power needed to blow the cooled air into the sub-floor plenum. ACU blower power is described in detail below.

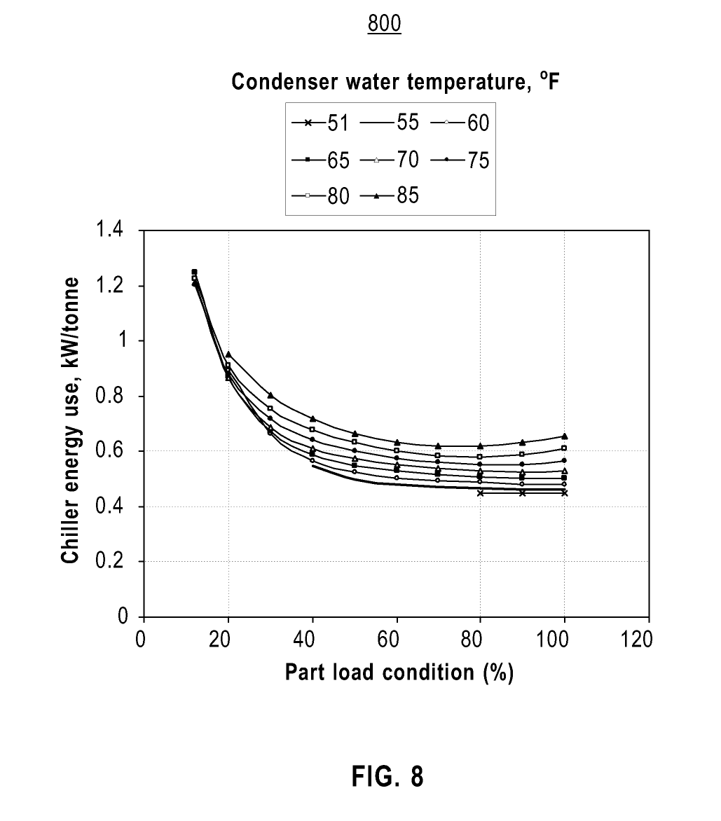

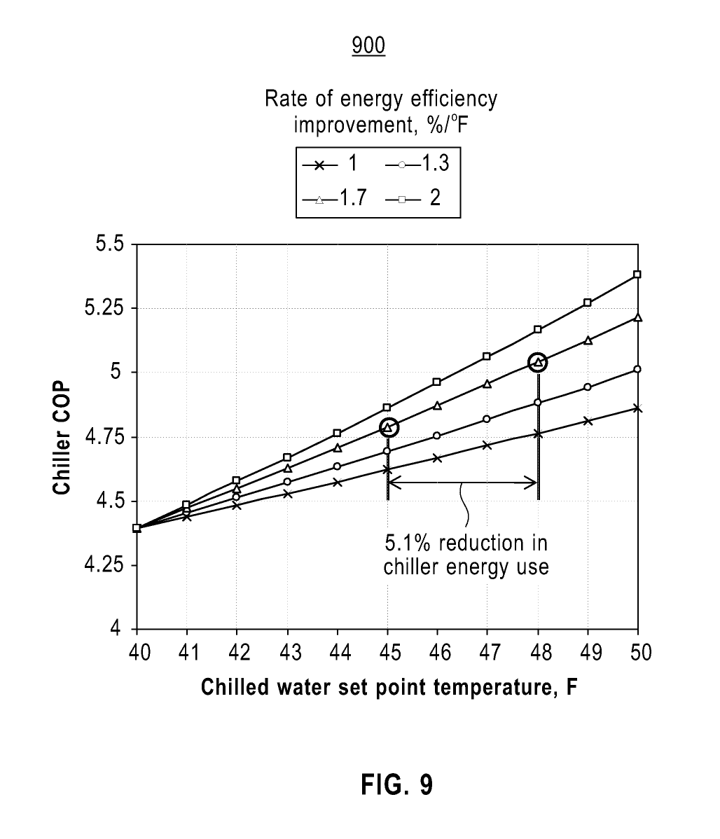

A refrigeration chiller plant is typically made up of several components, including a refrigeration chiller, a cooling tower, cooling tower pumps and blowers and building chilled water pumps. The refrigeration chiller itself comprises two heat exchangers connected to each other, forming a refrigerant loop (see below), which also contains a compressor for refrigerant vapor compression and a throttling valve for refrigerant liquid expansion. It is the efficiency of this refrigeration chiller that is shown in FIGS. 8 and 9, described below. One of the heat exchangers in the refrigeration chiller condenses refrigerant vapor (hereinafter “condenser”) and the other heat exchanger heats the refrigerant from a liquid to a vapor phase (hereinafter “evaporator”). Each of the heat exchangers thermally couples the refrigerant loop to a water loop. Namely, as described in detail below, the condenser thermally couples the refrigerant loop with a condenser water loop through the cooling tower and the evaporator thermally couples the refrigerant loop with a building chilled water loop.

The building chilled water loop comprises one or more pumps and a network of pipes to carry chilled water to the ACUs from the refrigerant loop, and vice versa. Specifically, the evaporator thermally couples the building chilled water loop) to the refrigerant loop, and allows the exchange of heat from the water to the refrigerant. The chilled water flows through heat exchanger coils in the ACUs. Hot air that is blown across the heat exchanger coils in the ACUs rejects its heat to the chilled water flowing therethrough. After extracting heat from the data center, the water, now heated, makes its way back to the evaporator where it rejects its heat to the refrigerant therein, thus being cooled back to a specified set point temperature. At the condenser, the refrigerant rejects the heat that was extracted at the evaporator into condenser water flowing therethrough.

This condenser water is pumped, by way of a pump and associated plumbing networks to and from the cooling tower. In the cooling tower, the heated condenser water is sprayed into a path of an air stream, which serves to evaporate some of the water, and thereby cooling down the remainder of the condenser water stream. A water source, i.e., a “make up” water source, is provided to ensure a constant condenser water flow rate. The air stream is typically created using the cooling tower blowers that blast huge volumetric air flow rates. i.e., 50,000-500,000 CFM, through the cooling tower. A fin structure can be utilized to augment the evaporation rate of the condenser water in the air flow path.

With regard to improving the cooling efficiency of data centers. it is useful to distinguish between two factors associated with cooling power consumption. The first factor is associated with the cost to generate cooled air (a thermodynamic term) and a second factor is associated with the delivery of the cooled air to a data center (a transport term). To a first order, the thermodynamic term of the cooling power, i.e., cooling energy, is determined by a power consumption of the refrigeration chiller, while the transport term is given by a power consumption of the ACU blower.

FIG. 7 is a diagram illustrating how best practices implemented with a raised-floor cooling system impact transport and thermodynamic factors of cooling power consumption in data center 700. Data center 700 has IT equipment racks 701 and a raised-floor cooling system with ACUs 702 that take hot air in (typically from above) and reject cooled air into a sub-floor plenum below. Hot air flow through data center 700 is indicated by light arrows 710 and cooled air flow through data center 700 is indicated by dark arrows 712.

In FIG. 7, the IT equipment racks 701 use front-to-back cooling and are located on raised-floor 706 with sub-floor 704 beneath. Space between raised floor 706 and sub-floor 704 defines the sub-floor plenum 708. The sub-floor plenum 708 serves as a conduit to transport, e.g., cooled air from the ACUs 702 to the racks. Data center 700 is arranged in a hot aisle—cold aisle configuration, i.e., having air inlets and exhaust outlets in alternating directions. Namely, cooled air is blown through perforated floor tiles 714 in raised-floor 706 from the sub-floor plenum 708 into the cold aisles. The cooled air is drawn into the IT equipment racks 701, via the air inlets, on an air inlet side of the racks and dumped, via the exhaust outlets, on an exhaust outlet side of the IT equipment racks 701 and in the hot aisles.

Hotspots, for example, within the raised floor, i.e., horizontal/vertical hotspots as opposed to sub-floor plenum hotspots, (here caused by intermixing of cold and hot air) can increase air temperatures at the air inlets of corresponding IT equipment racks. Such intermixing can occur, for example, as a result of violations of the hot/cold aisle concept, e.g., wherein IT equipment racks are arranged to form one or more mixed isles (isles in which both hot and cooled air is present). In order to compensate for these hotspots, data center managers often chose an excessively low chilled water temperature set point, (i.e., the temperature of the water being delivered to the ACUs from the refrigeration chiller, via the building chilled water loop (as described above) which can be set at the refrigeration chiller) which significantly increases the thermodynamic cooling cost at the refrigeration chiller (P_{chiller}). An excessively low chilled water temperature set point, for example about five ° C., results in an air temperature of about 12° C. at the perforated floor tiles, so as to offset a 15° C. temperature gradient between the tops and bottoms of the IT equipment racks. In this case, the inefficiency results in as much as a 10 percent to 25 percent increase in energy consumption at the refrigeration chiller. as compared to an optimized data center design. This constitutes a significant increase in thermodynamic cooling costs.

The term “hotspots,” as used herein, is intended to refer to region(s) of relatively higher temperature, as compared to an average temperature. Hotspots can occur on the sun, the human body. a microprocessor chip or a data center. The use of the term “relatively” is made to qualitatively define the size of a region, which is higher in temperature compared to the rest of the room. For example, if it is assumed that a hot region is anything that is hotter by one degree Celsius (° C.) compared to the average temperature. then one would likely find that a large part of the data center fulfils this condition. However. if it assumed that to be considered a hotspot, the region needs to be from about five ° C. to about 15° C. hotter than the average temperature. then the hotspot region will be much smaller. Therefore., by choosing a criteria for defining what is “hot” one indirectly influences the size of the hotspot region. If the phrase is interpreted as only slightly higher then the hotspots will be large. However, if the use of the phrase “relatively” means much higher, then the hot spot region will be relatively smaller. By way of example only, in a data center, hotspots can be identified as those regions of the data center having temperatures that are at least about five ° C. greater than, e.g., between about five ° C. and about 20° C., the average room temperature, and the hot spot region can be between about 10 percent and about 40 percent of the total room footprint area. Herein a distinction is further made between horizontal hotspots (i.e., referring to locations of relatively higher temperatures in a horizontal plane) and vertical hotspots (i.e., referring to locations of relatively higher temperatures in a vertical plane).

It is further shown in FIG. 7 that ACUs often are not effectively utilized. For example, it is common that one or more of the ACUs are just circulating air without actually reaching the air inlets of the IT equipment racks. In this instance, the ACU blower motors consume power (i.e., ACU blower power) (P_{ACU}) without actually contributing to cooling of the data center.

From a thermodynamic work perspective, the power consumption of the refrigeration chiller is governed by four dominant factors. These factors are: the chilled water temperature set point leaving the evaporator to provide cooling for the ACUs, a load factor (which is a ratio of an operating heat load of the refrigeration chiller to a rated heat load), a temperature of condenser water entering the condenser from the cooling tower (i.e., condenser water temperature) and an energy used in pumping water and air in both the building chilled water and the cooling tower loops, respectively.

FIG. 8 is a graph 800 illustrating a relationship between refrigeration. chiller power consumption and load factor for several different condenser water temperatures. In graph 800, variations of refrigeration chiller power consumption are shown (normalized) (measured in kilowatts/tonne (kW/tonne)) with load factor for different condenser water temperatures, measured in degrees Fahrenheit (° F.). The data for graph 800 was obtained from YORK (York, Pa.) manufacturers catalogue for a water-cooled 2,000 ton reciprocating piston design using R134-A.

Graph 800 illustrates that there is a dependence of refrigeration chiller power consumption on load and condenser water temperature, which are both difficult factors to control. Namely, while both of these factors, i.e., load and condenser water temperature, are important, they are usually determined by climatic and circumstantial parameters. For example, if the outdoor temperature in Phoenix, Ariz., is 120° F., then there is not much a data center best practices service can do about that. Similarly, if the IT equipment computing load is just not needed, then the refrigeration chiller will be at a low load factor condition.

Thus, according to an exemplary embodiment, focus is placed on the dependence of refrigeration chiller power consumption on the chilled water temperature set point, which is a parameter that can be easily and readily controlled by data center managers. As will be described in detail below, by implementing the proper best practices, the chilled water temperature set point can be increased, thereby saving thermodynamic energy of the refrigeration chiller.

Specifically, a one ° F. increase in the chilled water temperature set point results in approximately a 0.6 percent to a 2.5 percent increase in the refrigeration chiller efficiency. See, for example, Maximizing Building Energy Efficiency And Comfort—Continuous Commissioning Guidebook for Federal Energy Managers. A report published by Federal Energy Management Program (FEMP)—U.S. Department of Energy (DOE), Prepared by Texas A&M University and University of Nebraska, Chapter 6, page 2, October (2002), Kavita A. Vallabhaneni, Benefits of Water-Cooled Systems vs. Air-Cooled Systems for Air-Conditioning Applications, Presentation from the website of the Cooling Technology Institute; Improving industrial productivity through energy-efficient advancements—Energy Council for an Energy-Efficient Economy (ACEEE), http://www.progress-energy.com/Savers—Chiller Optimization and Energy Efficient Chillers, the disclosures of which are incorporated by reference herein.

A rate of energy efficiency improvement of 1.7 percent per ° F. (%/° F.) will be used herein to estimate energy savings. FIG. 9 is a graph 900 illustrating a relationship between energy efficiency of a refrigeration chiller and an increase in the chilled water temperature set point. In graph 900, coefficient of performance (COP) for the refrigeration chiller is plotted on the y-axis and chilled water temperature set point values (in ° F.) are plotted on the x-axis. As can be seen from graph 900, at a rate of energy efficiency improvement of 1.7%/° F., a reduction in refrigeration chiller energy consumption can be as high as 5.1 percent. The energy efficiency illustrated in FIG. 9, as well as in FIG. 8, described above, relates to refrigeration chiller efficiency. The impact on other parts of a cooling infrastructure, such as the cooling tower pumps, fans and the building chilled water pumps, are not considered because they are second order effects.

With regard to chilled air from ACUs, in order to reduce the transport term of power consumption in a data center, the ACU blower power has to be reduced. If the ACUs are equipped with a variable frequency drive (VFD), blower power can be saved continuously by simply throttling the blower motor.

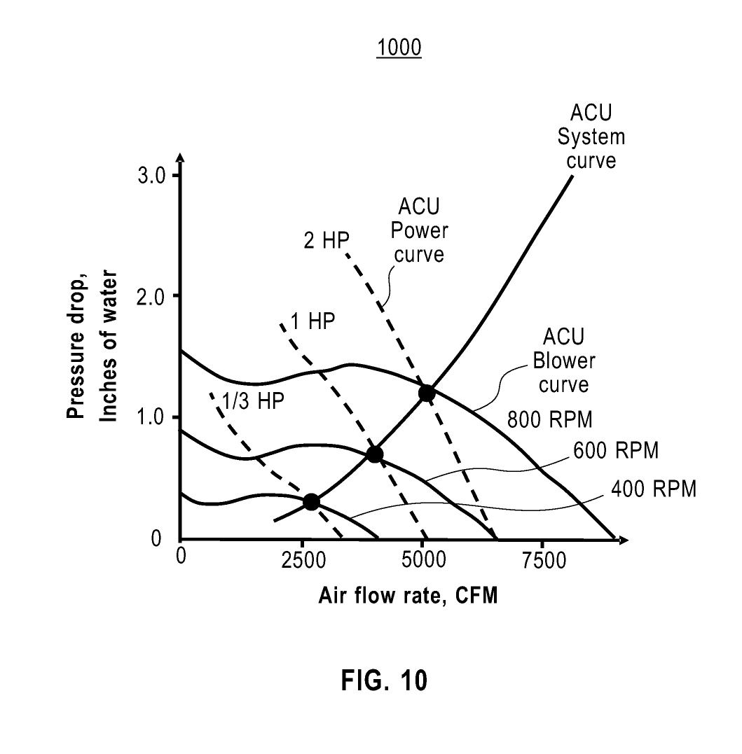

The respective energy improvements for different blower speeds are shown in FIG. 10. FIG. 10 is a graph 1000 illustrating hydraulic characteristic curves describing ACU blower power consumption using plots of pressure drop (measured in inches of water) versus volumetric air flow rate through the ACUs (measured in cubic feet per minute (CFM)). The ACU system curve is a simple quasi-quadratic relationship between the pressure drop across the ACU and the air flow rate through the ACU. As the air flows through various openings in the ACU, such as the heat exchanger coil, described above, and ACU air filters, the air accrues a loss in pressure due to expansion and contraction mechanisms, as well as due to friction through the ACU.

Thus, for a 5,100 CFM operating point, the pressure drop is a little more than one inch of water (about 250 Newtons per square meter (N/m²)) and the dotted lines show the blower motor power consumption to be about two horsepower (hp). The blower motor speed for this operating point is 800 revolutions per minute (RPM). Observing FIG. 10, it can seen that, on reducing the blower motor speed from 800 RPM to 600 RPM, the air flow rate reduces by 22 percent while the blower motor power consumption reduces by 50 percent (i.e., as compared to the blower motor at 800 RPM). This steep decrease in ACU blower motor power consumption for a modest reduction in air flow rate, i.e., from about 5,100 CFM to about 4,000 CFM, is due to the large decrease in the pressure drop, i.e., from about 250 N/m² to about 90 N/m².

If the blower motor speed is further reduced to 400 RPM, thus decreasing the air flow rate to half of what it was at 800 RPM, then the blower motor power consumption is reduced by a large factor of 84 percent. It should be noted that the preceding discussion does not take the pressure loss and thus pumping work due to the sub-floor plenum and the perforated tiles. This component is usually about 10 percent to about 15 percent of the total ACU power consumption.

In most cases. however, ACU blowers cannot be controlled. Thus, for the following discussion it is assumed that blower power savings come from turning off the respective ACUs.

As described, for example, in conjunction with the description of step 108 of FIG. 1, above, physical parameter data are collected from the data center. A key component of the present techniques is the ability to rapidly survey a customer data center. U.S. Patent Application No. 2007/0032979 filed by Hamann et al., entitled “Method and Apparatus for Three-Dimensional Measurements,” the disclosure of which is incorporated by reference herein, describes a mobile measurement technology (MMT) for systematic, rapid three-dimensional mapping of a data center by collecting relevant physical parameters.

The MMT is the only currently available method to rapidly measure the full three-dimensional temperature distribution of a data center. The MMT can play an important role in the data collecting process. For example, the MMT can yield three-dimensional thermal images of the data center, such as that shown in FIG. 11. FIG. 1I is an exemplary three-dimensional thermal image 1100 of a data center generated using MMT, showing hotspots 1102. The data from an MMT scan is not only important to actually diagnose and understand energy efficiency problems, but is also useful to help quantify a degree of best practices. The data from an MMT scan also provides an excellent means to communicate to the customer the actual issues, thereby empowering the customer to implement the respective recommendations.

Specifically, the MMT uses a plurality of networked sensors mounted on a framework, defining a virtual unit cell of the data center. The framework can define a cart which can be provided with a set of wheels. The MMT has a position tracking device. While rolling the cart through the data center, the MMT systematically gathers relevant physical parameters of the data center as a function of orientation and x, y and z positions.

The MMT is designed for low power consumption and is battery powered. The MMT can survey approximately 5,000 square feet of data center floor in only about one hour. As described, for example, in conjunction with the description of FIG. 1, above, relevant physical parameters include, but are not limited to, temperature, humidity and air flow. The MMT samples humidity and temperature.

Other measurement tools may be used in addition to the MMT. By way of example only, air flow data can be collected using a standard velometer flow hood, such as the Air Flow Capture Hood also manufactured by Shortridge Instruments, Inc. Namely, a standard velometer flow hood can be used to collect air flow rate data for the different perforated floor tiles. According to an exemplary embodiment, the flow hood used fits precisely over a two foot by two foot tile. Further, power measurements, including measuring a total power supplied to a data center. can be achieved using room level power instrumentation and access to PDUs. PDUs commonly have displays that tell facility managers how much electrical power is being consumed. ACU cooling power can be computed by first measuring ACU inlet air flow using a flow meter, such as The Velgrid, also manufactured by Shortridge Instruments, Inc., or any other suitable instrument, by spot sampling and then ACU air inlet and exhaust outlet temperatures can be measured using a thermocouple, or other suitable means. The cooling done by and ACU is directly proportional to the product of its air flow and the air temperature difference between the air inlet and exhaust outlet. respectively.

As described above, a goal of the present teachings is to improve the energy and space efficiency of a data center. This can be achieved by making two important changes to the cooling infrastructure, namely (1) lowering the chilled water temperature set point (learning the evaporator) and thus reducing power consumption by the refrigeration chiller (thermodynamic) and (2) lowering the air flow supplied by the ACUs, thus reducing the ACU blower power consumption (transport).

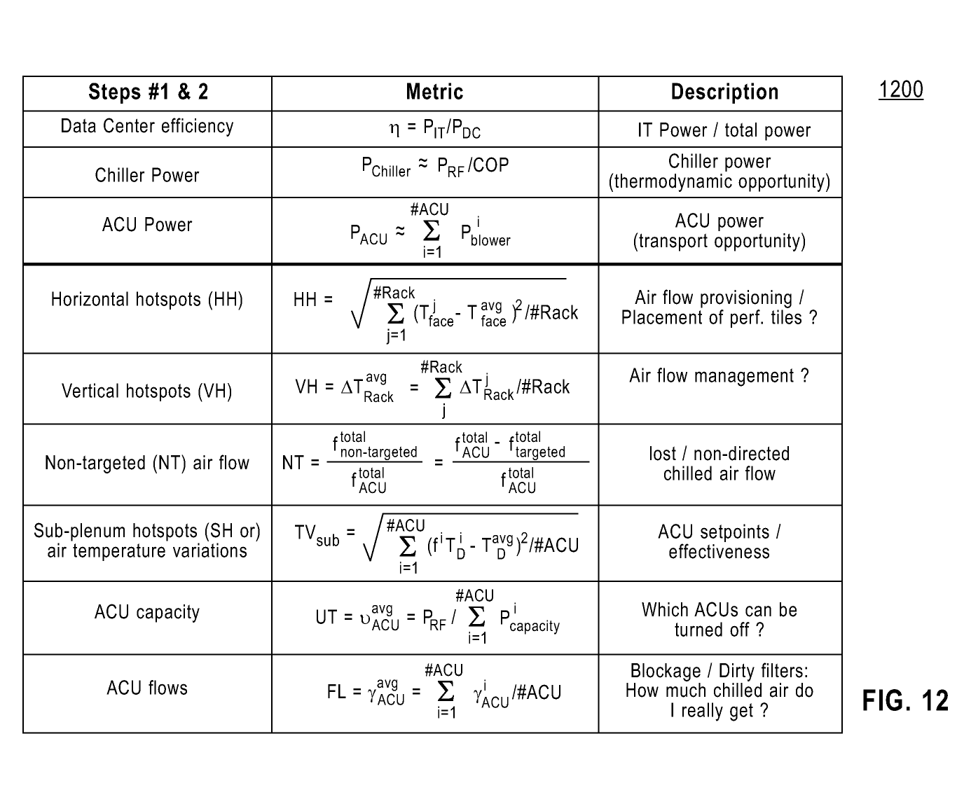

As described above, the present techniques involve a number of measurements/metrics. For example, methodology 100, described in conjunction with the description of FIG. 1, above, involves making an initial assessment of data center efficiency (step 102), making an estimation of ACU and refrigeration chiller power (step 104) and compiling physical parameter data into six key metrics (step 110). FIG. 12 is a table 1200 that illustrates these measurements/metrics.

As described, for example, in conjunction with the description of step 102 of FIG. 1, above, in the initial phase of methodology 100 data center energy efficiency (η) is measured by:

η=P_{IT}/P_{DC}. (1)

The total power for the data center (P_{DC}) is typically available from facility power monitoring systems or from the utility company and the IT equipment power (P_{IT}) can be directly measured at the PDUs present throughout the data center. Most PDUs have power meters, but in cases where they do not, current clamps may be used to estimate the IT equipment power.

As described, for example, in conjunction with the description of step 104 of FIG. 1, above, an estimation is made of ACU and refrigeration chiller power. ACU power consumption (P_{ACU}) (transport) can be determined by adding together all of the blower powers P_{blower}ⁱ for each ACU, or by multiplying an average blower power P_{blower}^{avg} by a numbers of ACUs (#ACU) present in the data center (neglecting energy consumption due to dehumidification) as follows:

$${P}_{ACU} \approx {\sum }_{i = 1}^{\# ACU} {P}_{blower}^{i} = \# ACU \cdot {P}_{blower}^{avg} . \qquad ( 2 )$$

Due to one or more of condensation at the cool heat exchanger coils of the ACU, the existence of human beings in the data center who “sweat” moisture into the room, as well as the ingress of external dry or moist air into the room, the humidity of the data center needs to be controlled, i.e., by dehumidification. The dehumidification function carried out by the ACU serves this purpose. The refrigeration chiller power (P_{chiller}) (thermodynamic) is often available from the facility power monitoring systems. Otherwise, P_{chiller} can be approximated by estimating the total raised-floor power (P_{RF}) (i.e., total thermal power being removed by the ACUs, which includes the power of the ACUs themselves) and an anticipated coefficient of performance for the refrigeration chiller (COP_{chller}), as follows:

P_{chiller}=P_{RF}/COP_{chiller}. (3)

Here a COP_{chiller} of 4.5 can be used, corresponding to 0.78 kW/tonne, which is typical for a refrigeration chiller. The total raised floor power (P_{RF}) is given by the following:

P_{RF}=P_{IT}+P_{light}+P_{ACU}+P_{PDU}. (4)

wherein P_{light} represents power used for lighting in the data center, P_{ACU} represents total ACU power and P_{PDU} represents the power losses associated with the PDUs. P_{IT} is, by far, the largest term and is known from the PDU measurements for the data center efficiency as described, for example, with reference to Equation 1, above. The power used for lighting is usually small and can be readily estimated by P_{light}≈A_{DC}·2 W/ft², wherein A_{DC} is the data center floor area and an estimated two Watts per square foot (W/ft²) are allocated for lighting. Typical PDU losses are on the order of about 10 percent of the IT equipment power (i.e., P_{PDU}≈P_{IT} 0.1).

As is shown in Table 1200, the different metrics have been grouped by thermodynamic and transport type of energy savings (increase the chilled water temperature set point and turn ACUs off (or implement variable frequency drives), respectively). While the distinction between thermodynamic and transport type energy savings is straightforward for hotspots, the distinction is less clear for flow contributions. It is also noted that this distinction is useful for clarification purposes but that certain metrics, depending on the choice of the energy saving action (e.g., turn ACUs off and/or change the chilled water temperature set point) can be both thermodynamic and/or transport in nature.

With regard to temperature distribution and hotspots, hotspots are one of the main sources for energy waste in data centers. It is notable. however, that in a typical data center a relatively small number of the IT equipment racks are hot, and these racks are generally located in specific areas, i.e., localized in clusters. In addition, it is quite common that IT equipment, such as servers and nodes in higher positions on a rack are the hottest. An energy-costly solution involves compensating for these hotspots by choosing a lower chilled water temperature set point, which disproportionately drives up energy costs for a data center.

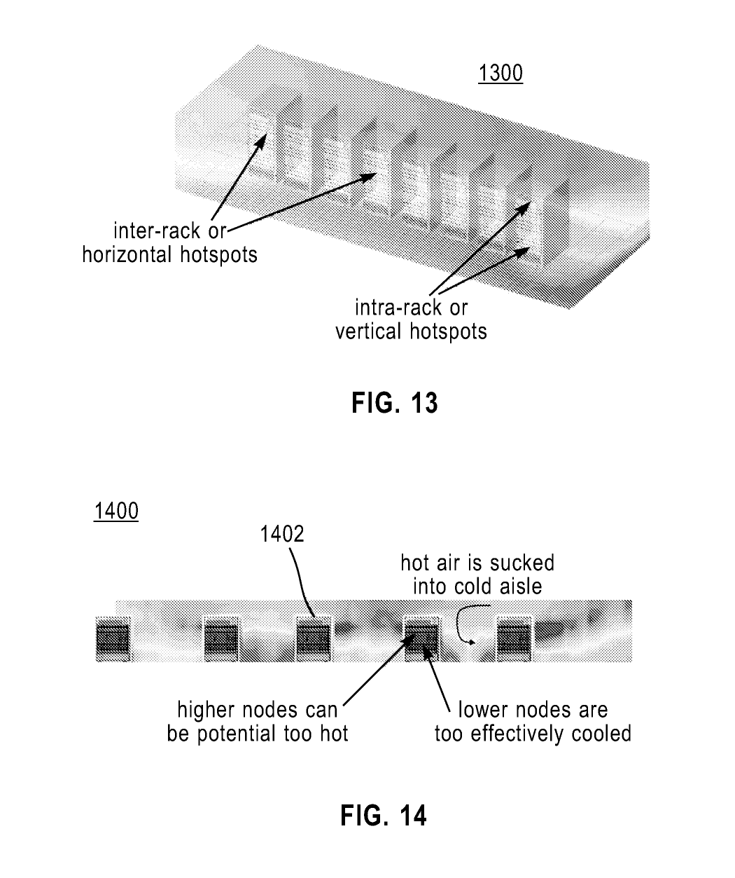

FIG. 13 is a diagram illustrating MMT scan 1300 which provides a three-dimensional temperature field for pinpointing hotspots within a data center. Generally, hotspots arise because certain regions of the data center are under-provisionied (undercooled) white other regions are potentially over-provisioned (overcooled). The best way to understand the provisioning is to measure the power levels in each rack, e.g., at each server, which is typically not possible in a timely manner.

In the following discussion, a distinction is made between horizontal and vertical hotspots, because the respective solutions are somewhat different. It is also noted that the techniques described herein correlate each of the metrics with action-able recommendations.

A horizontal hotspot metric (H_{HH}) is defined as follows:

$$HH = {T}_{face}^{std} = \sqrt{{\sum }_{j = 1}^{\# Rack} {( {T}_{face}^{j} - {T}_{face}^{avg} )}^{2} / \# Rack} , \qquad ( 5 )$$

wherein HH is a standard deviation of the average IT equipment rack inlet (face) temperatures (T_{face}^{j}), i.e. measured at the fronts of each IT equipment rack wherein cooled air is drawn, for each rack in the data center (j=1 . . . #RACK). The IT equipment rack air inlet (face) temperatures are taken from an MMT thermal scan made of the data center. See, step 108 of FIG. 1, above. T_{face}^{avg} is the average (mean) temperature of all IT equipment rack air inlet (face) temperatures in the data center under investigation, namely

$${T}_{face}^{ave} = {\sum }_{j = 1}^{\# Rack} {T}_{j}^{face} / \# Rack . \qquad ( 6 )$$

In some cases, the IT equipment racks are not completely filled, i.e., and have one or more empty slots. In that instance, temperatures for the empty slots are excluded from the calculation. It is noted that a histogram or frequency distribution (h_{HH}(T_{face}^{j})) of the IT equipment rack air inlet (face) temperatures with its average (mean) temperature (T_{face}^{avg}) and standard deviation (T_{face}^{std}) is another important metric in helping to gauge and understand the extent of horizontal hotspots and how to mitigate them. Namely, the horizontal hotspot metric (Equation 5) can be computed for each IT equipment air inlet, or for each IT equipment rack air inlet, and the histograms based on this computation can locate and identify a spatial extent of each hotspot. In addition, it is noted that T_{face}^{avg} can be used to determine whether or not the whole data center is overcooled. For example, the mean temperature should ideally be centered in the desired operating temperature range. If the mean temperature is below (or above) this value, the data center is overcooled (or undercooled). It is assumed that hotspots have been managed at least to the extent that the range of IT equipment rack air inlet (face) temperatures corresponds to the range in the measured data of the IT equipment rack air inlet (face) temperatures specification. Typical values of a server inlet temperature specification are between about 18° C. to about 32° C.

Although the correct allocation of required air flow to each IT equipment rack is an important part of best practices (i.e., low H_{HH}), experience has shown that simply provisioning the right amount of air flow does not always mitigate hotspots and that there are some limits to this approach. For example, additional restrictions, such as within rack recirculation and recirculation over and/or around racks, can inhibit air flow and create intra-rack or vertical hotspots. In particular, nodes and servers located at the top of an IT equipment rack experience hotspots from poor air flow management (e.g., resulting in recirculation (see, for example, FIG. 7)) rather than appropriate provisioning.

FIG. 14. is a diagram illustrating vertical temperature map 1400, measured by an MMT thermal scan, demonstrating large temperature gradients between bottoms and tops of IT equipment racks 1402, e.g., as low as 13° C. at the bottoms and as high as 40° C. at the tops. FIG. 14 shows how IT equipment components, i.e. servers. at bottoms of IT equipment racks 1402 are “overcooled” while servers at tops of IT equipment racks 1402 do net get the cooled air they require, and thus are “undercooled.” For example, if a recommended server inlet temperature is about 24° C., and inlet air to the servers at the bottom of the rack is at about 13° C. then these servers are overcooled, and conversely, at the top of the rack if the server air inlet temperatures are 40° C., then these servers are undercooled. In order to quantify vertical hotspots, an average is taken of the difference between the lowest and highest server ΔT^{j}_{Rack} in each rack, as follows:

$$VH = Δ {T}_{Rack}^{avg} = {{\sum }_{i}}^{\# Rack} Δ {T}_{Rack}^{j} / \# Rack \qquad ( 7 )$$

for j=1 . . . #Rack. Equation 7 is a vertical hotspots metric. A respective histogram (frequency) distribution (h_{VH}(ΔT_{Rack}^{j})) with its associated standard deviation (ΔT_{Rack}^{std}) is a more detailed way to understand a degree of vertical hotspots, as the histogram highlights vertical hotspot values corresponding to poor provisioning or air recirculation.

While placement of the perforated floor tiles will mostly affect horizontal hotspots (and to some extent vertical hotspots), in a typical data center a significant fraction of the air flow is not targeted at all and comes, for example, through cable cutouts and other leak points. The present techniques quantify the fraction of non-targeted (NT) air flow as follows:

$$NT = \frac{{f}_{non - targeted}^{total}}{{f}_{ACU}^{total}} = \frac{{f}_{ACU}^{total} - {f}_{targeted}^{total}}{{f}_{ACU}^{total}} , \qquad ( 8 )$$

wherein f_{ACU}^{total} is total air flow output from all ACUs within a data center, and wherein f_{targeted}^{total} is determined according to Equation 12, presented below. Equation 8 is a non-targeted air flow metric

Because the quantitative measurement of ACU air flows is non-trivial, a simple method is used for estimating f_{ACU}^{total} using a combination of balancing dissipated energy within the data center and allocating this energy between the different ACUs (based on relative flow measurements) yielding,

$${f}_{ACU}^{total} \approx \frac{1}{ρ {c}_{p}} {\sum }_{i = 1}^{\# ACU} {P}_{cool}^{i} / Δ {T}_{ACU}^{i} , \qquad ( 9 )$$

wherein P_{cool}ⁱ is the power cooled by the respective ACU, and ΔT_{ACU}ⁱ is a difference between ACU return (T_{R}ⁱ) and ACU discharge (T_{D}ⁱ) temperatures, respectively (i.e., ΔT_{ACU}ⁱ=T_{ACU,R}ⁱ−T_{ACU,D}ⁱ). ACU return temp is the air temperature at a draw, i.e., suction, side of the ACU, i.e., the hot air temperature at an air inlet to the ACU, and ACU discharge temp is the cool air temperature as it leaves the ACU into the sub-floor plenum. ρ and cₚ are the density and specific heat of air, respectively (p≈1.15 kilograms per cubic meter (kg/m³), cₚ≈1007 Joules per kilogram Kelvin (J/kg K)). For this analysis, temperature dependence of air density and specific heat are ignored.

While it is straightforward to measure actual return and discharge temperatures for each ACU unit, the respective ACU cooling power levels P_{cool}ⁱ are more difficult to measure. However, one can a exploit a notion that the total raised-floor power (P_{RF}), i.e., total power dissipated in the raised-floor area, should be equal (to a first order) to a sum of each ACU cooling power for all ACUs, i.e.,

$${P}_{RF} \approx {\sum }_{i = 1}^{\# ACU} {P}_{cool}^{i} . \qquad ( 10 )$$

By measuring a non-calibrated air flow f_{ACU,NC}ⁱ from each ACU, as well as a difference between the return and discharge temperatures (ΔT_{ACU}ⁱ) for each ACU, a relative cooling power contribution (w_{cool}ⁱ=f_{ACU,NC}ⁱΔT_{ACU}ⁱ) can be allocated for each ACU and used to derive the respective power cooled at each ACU as follows:

$${P}_{ACU . cool}^{i} \approx {P}_{RF} {w}_{i} / {\sum }_{i = 1}^{\# ACU} {w}_{i} . \qquad ( 11 )$$

Apportioning an estimated total air flow in a data center to each individual ACU in the data center can be used to assess performance of the individual ACUs. This involves knowing a relative airflow of each ACU, rather than an actual airflow. Acu relative air flow measurements can be performed by sampling air flow rates (using, for example. The Velgrid or a vane anemometer) at a given location in the air inlet duct of the ACUs. In the event that the ACUs are of different models and thus potentially possessing different air inlet. i.e., suction, side areas. the area of the ACU unit needs to be accounted for in the calculations. This can be done by multiplying the ACU suction side area by the flow rate (measured using the flow meter at a single location). A single airflow measurement using standard flow instrumentation can be made for each ACU, which can be assumed to represent a fixed percentage of actual ACU airflow. This assumption can be validated, if desired, by making more complete measurements on the ACU. In cases where the ACU models differ, the different areas and geometrical factors can be accounted for, which can also be validated with more detailed flow measurements

According to an exemplary embodiment, for each ACU, the discharge temperature is measured by creating a small gap between floor tiles within 750 millimeters (mm) below the ACU. For example, one of the solid floor tiles can be lifted to create a small gap of about one inch to about two inches for access to the sub-floor plenum. Then a thermocouple can be put into the sub-floor plenum to measure sub-floor air temperature near this ACU and assume it to be the ACU discharge temperature. A thermocouple is placed in the gap and allowed to stabilize. The ACU return temperature is measured at a location 125 mm from a lateral side of the ACU and centered over the front filter in the depth direction, i.e., from a top down. This location is chosen so as to be proximate to an air inlet temperature sensor on the ACU. The readings typically fluctuate and generally are about two ° F. to about four ° F. above a temperature reported by the air inlet temperature sensor on the ACU.

Targeted air flow can be readily determined by measuring air flow from each perforated floor tile with a standard velometer flow hood, such as the Air Flow Capture Hood. In order to avoid double-counting the tiles, only the perforated floor tiles which are located in front of, or close by., i.e., within 10 feet of, the air inlet of an IT equipment rack are counted. Specifically, perforated floor tiles which are more than ten feet away from any IT equipment component, i.e. server, are counted towards non-targeted air flow. Targeted air flow is thus determined as follows:

$${f}_{targeted}^{total} = {\sum }_{j = 1}^{\# Racks} {f}_{perf}^{j} . \qquad ( 12 )$$

It is notable that fresh air for working personnel in the data center, commonly provided via ceiling vents, originates from outside of the data center. This air supply is distinguished from the data center cooling loop in which air is recirculated.

It is common that some ACUs are not set to a correct temperature, i.e., do not have correct temperature set points, or are not contributing, in any way. to cooling of the data center. In fact, it is not unusual that some ACUs actually hinder a cooling system by blowing hot return air into the sub-floor plenum air supply without proper cooling. This effect will increase sub-floor plenum temperatures or cause sub-floor plenum hotspots (SH). Sub-floor plenum hotspots can be counteracted by reducing the refrigeration chiller temperature set point (i.e., reducing the chilled water temperature set point), at an expensive energy cost. In order to gauge the impact of sub-floor plenum temperature variations, a standard deviation of ACU discharge temperatures weighted with relative flow contributions w_{flow}ⁱ, i.e., to the sub-floor plenum air supply, from each active ACU (ACUs that are turned off are accounted for in the determination of non-targeted air flow, i.e., if they leak cold air from the sub-floor plenum) is calculated, determining SH metric as follows:

$$SH = {T}_{sub}^{std} = \sqrt{{\sum }_{i = 1}^{\# ACU} {( {w}_{flow}^{i} {T}_{D}^{i} - {T}_{sub}^{avg} )}^{2} / \# ACU} , \qquad ( 13 )$$

wherein T_{sub}^{avg} is an average sub-floor plenum temperature, i.e.,

$${T}_{sub}^{avg} = {\sum }_{i = 1}^{\# ACU} {w}_{flow}^{i} \cdot {T}_{D}^{i} , \qquad ( 14 )$$

wherein the relative flow contributions w_{flow}ⁱ from each active ACU is determined as follows:

$${w}_{flow}^{i} = {f}_{ACU . NC}^{i} / {\sum }_{i = 1}^{\# ACU} {f}_{ACU . NC}^{i} . \qquad ( 15 )$$

An important gauge as to whether an ACU needs to be examined is given by a discharge temperature (T_{D}ⁱ) in combination with the ACU utilization. Typical ACU discharge temperatures are on an order of about 60° F. (which can be determined by the refrigeration chiller temperature set point). The respective utilization ν_{ACU}ⁱ for each ACU (i) can be determined as follows:

ν_{ACU}ⁱ=P_{cool}ⁱ/P_{capacity}ⁱ, (16)

wherein P_{capacity}ⁱ is a specified cooling capacity of the ACU. Overloaded (over-utilized) ACUs (i.e., wherein ν_{ACU}ⁱ>>1) will show slightly higher discharge temperatures, which is normal. However, an under-utilized ACU (i.e., ν_{ACU}ⁱ>>1) will often have high discharge temperatures (e.g., T_{D}ⁱ>60° F.), which might be caused, for example, by a congested water supply line to the ACU, by an overloading of the refrigeration chiller or by wrong temperature set points on the ACU. In order to diagnose ACU over/under-utilization in a data center, an ACU effectiveness is defined as follows:

for ν_{ACU}ⁱ>1, ε_{ACU}ⁱ=T_{D}^{min}ν_{ACU}ⁱ/T_{D}ⁱ, and (17)

for ν_{ACU}ⁱ≦1, ε_{ACU}ⁱ=/T_{D}^{min}/T_{D}ⁱ, (18)

wherein T_{D}^{min} is a minimum (smallest) measured discharge temperature in the data center. Using the ACU effectiveness measurements, a customer can gauge whether an ACU should be looked at. Typically, ACUs with an effectiveness of less than about 90 percent should be inspected, as these ACUs increase the sub-floor plenum temperatures. which can increase energy costs. An ACU sub-floor plenum hotspot histogram distribution (h_{SH}(w_{flow}ⁱ−T_{D}ⁱ)) with its average (mean) (T_{sub}^{avg}) and standard deviation (T_{sub}^{std}) can also be defined to help customers better understand the efficacy of the ACUs. For example, the histogram would be helpful in identifying locations of congestion, e.g., due to cable pileup.

In a data center more ACUs are typically running than are actually needed. As such. an ACU utilization (UT) metric (Equation 19, below) can be useful to understanding possible energy savings associated with transport. An average ACU utilization (ν_{ACU}^{avg}) within a data center can be estimated as follows:

$$UT = {υ}_{ACU}^{avg} = {P}_{RF} / {\sum }_{i = 1}^{\# ACU} {P}_{capacity}^{i} . \qquad ( 19 )$$

While the average ACU utilization can be readily estimated (e.g., as in Equation 19, above) and in some cases is known by data center managers, the present techniques provide a detailed look at ACU utilization. Specifically, the utilization for each individual ACU can be derived as follows:

ν_{ACU}ⁱ=P_{cool}ⁱ/P_{capacity}ⁱ (20)

and ACU utilization histogram frequency distribution (h_{UT}(ν_{ACU}ⁱ)) with its standard deviation (ν_{ACU}^{std}) can be defined, which gives a client a detailed way to understand how heat load in the data center is distributed between the different ACUs within the data center and which ACUs may be turned off with the least impact. Namely, the histogram makes anomalous performance visible by showing outliers and extreme values. In addition. the customer can understand what would happen if a certain ACU should fail, which can help in planning for an emergency situation.

Ideally, an energy efficient data center has a very narrow frequency distribution centered at about 100 percent ACU utilization. Typical data centers, however, have average frequency distributions on the order of about 50 percent. Because most data centers require an N+1 solution for the raised floor, i.e., the ability to tolerate the failure of any one ACU. it may be advisable to position the average of the frequency distribution not quite to 100 percent. but to ≈(#ACU−1)/#ACU (e.g., a data center with ACUs would try to target a mean utilization of 90 percent with a standard deviation of less than 10 percent).

Several options exist for improving ACU utilization. Leaving aside variable frequency drive (VFD) options, as described above, a first option for improving ACU utilization involves turning off one or more ACUs and a second option for improving ACU utilization involves increasing the raised-floor power consumption, i.e., total raised-floor power P_{RF}, to better match the IT power to the ACU capacity. It is notable that any ACUs that are turned off need to be sealed so that they do not serve as an outlet for the cold sub-floor plenum air, and thus do not add significantly to leakage contribution.

Often one or more of blockage, dirty filters and low throughput perforated floor tiles hinder or prevent the ACU blowers from delivering air flow to the IT equipment racks, which is an additional energy loss term. According to the present techniques, this effect is quantized by an average air flow capacity (γ_{ACU}^{avg}), also referred to as an ACU air flow, which can be determined as follows:

$$FL = {γ}_{ACU}^{avg} = {\sum }_{i = 1}^{\# ACU} {γ}_{ACU}^{i} / \# ACU , \qquad ( 21 )$$

wherein γ_{ACU}ⁱ is the air flow capacity. Equation 21 is an ACU air flow metric. The air low capacity γ_{ACU}ⁱ is defined as:

γ_{ACU}ⁱ=f_{ACU}ⁱ/f_{capacity}ⁱ, (22)

wherein f_{capacity}ⁱ is the nominal air flow specified, e.g., by the ACU manufacturer and f_{ACU}ⁱ is an actual, calibrated, measured air flow from each ACU. The actual air flow from each ACU f_{ACU}ⁱ can be determined from non-calibrated flow measurements (f_{ACU,MC}ⁱ) and the total air flow in the data center (f_{ACU}^{total}) (see, e.g., Equation 9, above), as follows:

$${f}_{ACU}^{i} = {f}_{ACU . NC}^{i} {f}_{ACU}^{total} / {\sum }_{i = 1}^{\# ACU} {f}_{ACU . NC}^{i} . \qquad ( 23 )$$

A distribution of this flow capacity h_{FL} (γ_{ACU}ⁱ) and a respective standard deviation γ_{ACU}^{std} is a gauge for the degree of blockage, e.g., air clogged air filters, and effectiveness of ACU flow delivery.

The essence of the present techniques is to provide customers with a clear yard stick so that they can manage the implementation of best practices. FIG. 15 is a table 1500 illustrating metrics, key actions that can be taken and expected energy savings. A detailed discussion about the different recommendations and solutions to improve data center thermal/energy metrics now follows.

With regard to horizontal hot spots (HH), the different measures that can be undertaken to alleviate horizontal hot spots are making changes in the perforated floor tile layout, deploying higher throughput (HT) perforated floor tiles, using curtains and filler panels, installing the Rear Door Heat eXchanger™ (referred to hereinafter as “Cool Blue”) and/or changing the IT equipment rack layout, such spreading out the racks so that they are not clustered in one area and are not brick-walled to one another. Curtains are barriers placed above and between IT equipment racks and across isles to prevent air recirculation and mixing. Filler panels are flat plates, i.e., baffles, placed over empty equipment areas to prevent, i.e., internal, exhaust recirculation inside the racks.

The vertical hotspots can be addressed by changing the perforated floor tile layout, deploying higher throughput perforated floor tiles, using filler panels, making facility modifications so as to include a ceiling return for the hot exhaust air, increasing ceiling height and/or installing air redirection partial duct structures over the air inlets and/or exhaust outlets of the IT equipment. These air redirection partial duct structures are also referred to herein as “snorkels.” The air redirection ducts can be semi-permanently attached to the ACU and can serve to prevent air recirculation and exhaust-to-inlet air flow. See commonly owned U.S. application Ser. No. ______ entitled “Techniques for Data Center Cooling.” designated as Attorney Reference No. YOR920070177US1. filed herewith on the same day of May 17, 2007, the disclosure of which is incorporated by reference herein.

With regard to non-targeted air flow (NT), the best practices approach of the present teachings mitigates the non-targeted air flow by sealing leaks and cable cut out openings and simultaneously deploying higher throughput perforated floor tiles. With regard to sub-floor plenum temperature variations/hotspots (SH), faulty ACUs are fixed by opening water valves, unclogging pipes and/or using larger diameter pipe.

The ACU utilization (UT) is improved by turning off ACUs, incorporating variable frequency drive (VFD) controls at the blower and/or installing air redirection partial duct structures on the ACU. For example, extending an air inlet of the ACU vertically i.e., by way of an air redirection partial duct structure (as described above), can raise the hot air level in the data center. Ducting can be employed to extend the air inlet of the ACU to hot isles, or even directly to an exhaust(s) of particular equipment, to improve air collection efficiency. The ACU flow (FL) ratio is enhanced by performing maintenance on the ACU, which might entail cleaning the heat exchanger coils and replacing the air filters. Sub-floor plenum blockages should also be identified and removed so that as many sources of burdensome flow resistance in the air flow path of the ACU blower are removed.

The energy efficiency improvements, i.e. defined by the above metrics, can directly translate into energy savings. For example, in FIGS. 7 and 11, described above, which depict the transport and thermodynamic work terms, respectively, (e.g., FIG. 7 shows the transport work terms via arrows and a graphic depiction and FIG. 11 shows the hotspot in the horizontal plane which illustrates the thermodynamic inefficiency) the ACU air flow and temperature benefits that accrue from improving the various metrics discussed above can be “cashed in” by a customer in return for data center energy savings.

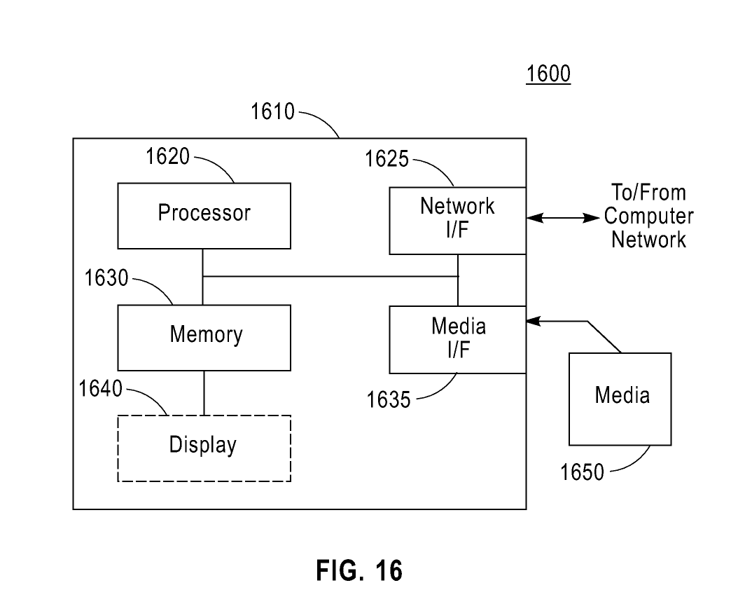

Turning now to FIG. 16, a block diagram is shown of an apparatus 1600 for analyzing energy efficiency of a data center having a raised-floor cooling system with at least one air conditioning unit in accordance with one embodiment of the present invention. It should be understood that apparatus 1600 represents one embodiment for implementing methodology 100 of FIG. 1.

Apparatus 1600 comprises a computer system 1610 and removable media 1650. Computer system 1610 comprises a processor 1620, a network interface 1625, a memory 1630, a media interface 1635 and an optional display 1640. Network interface 1625 allows computer system 1610 to connect to a network. while media interface 1635 allows computer system 1610 to interact with media, such as a hard drive or removable media 650.

As is known in the art., the methods and apparatus discussed herein may be distributed as an article of manufacture that itself comprises a machine-readable medium containing one or more programs which when executed implement embodiments of the present invention. For instance, the machine-readable medium may contain a program configured to make an initial assessment of the energy efficiency of the data center based on one or more power consumption parameters of the data center; compile physical parameter data obtained from one or more positions in the data center into one or more metrics if the initial assessment indicates that the data center is energy inefficient; and make recommendations to increase the energy efficiency of the data center based on one or more of the metrics.

The machine-readable medium may be a recordable medium (e.g., floppy disks, hard drive, optical disks such as removable media 1650, or memory cards) or may be a transmission medium (e.g., a network comprising fiber-optics, the world-wide web, cables, or a wireless channel using time-division multiple access, code-division multiple access, or other radio-frequency channel). Any medium known or developed that can store information suitable for use with a computer system may be used.

Processor 1620 can be configured to implement the methods, steps, and functions disclosed herein. The memory 1630 could be distributed or local and the processor 1620 could be distributed or singular. The memory 1630 could be implemented as an electrical, magnetic or optical memory, or any combination of these or other types of storage devices. Moreover, the term “memory” should be construed broadly enough to encompass any information able to be read from, or written to, an address in the addressable space accessed by processor 1620. With this definition, information on a network, accessible through network interface 1625, is still within memory 1630 because the processor 1620 can retrieve the information from the network. It should be noted that each distributed processor that makes up processor 1620 generally contains its own addressable memory space. It should also be noted that some or all of computer system 1610 can be incorporated into an application-specific or general-use integrated circuit.

Optional video display 1640 is any type of video display suitable for interacting with a human user of apparatus 1600. Generally, video display 1640 is a computer monitor or other similar video display.

It is to be further appreciated that the present invention also includes techniques for providing data center best practices assessment/recommendation services. By way of example only, a service provider agrees (e.g., via a service level agreement or some informal agreement or arrangement) with a service customer or client to provide data center best practices assessment/recommendation services. That is, by way of example only, in accordance with terms of the contract between the service provider and the service customer, the service provider provides data center best practices assessment/recommendation services that may include one or more of the methodologies of the invention described herein.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A method for analyzing energy efficiency of a data center having a raised-floor cooling system with at least one air conditioning unit, the method comprising the steps of:
making an initial assessment of the energy efficiency of the data center based on one or more power consumption parameters of the data center;
compiling physical parameter data obtained from one or more positions in the data center into one or more metrics if the initial assessment indicates that the data center is energy inefficient; and
making recommendations to increase the energy efficiency of the data center based on one or more of the metrics.

2. The method of claim 1, wherein the cooling system further comprises at least one refrigeration chiller adapted to supply chilled water to the air conditioning unit, the method further comprising the step of:
making an initial assessment of one or more of an air conditioning unit power consumption and a refrigeration chiller power consumption.

3. The method of claim 1, wherein the data center power consumption parameters comprise information technology power consumption and overall data center power consumption, and the initial assessment of the energy efficiency of the data center is based on a ratio of the information technology power consumption to the overall data center power consumption.

4. The method of claim 1, wherein the physical parameter data comprise one or more of temperature and humidity data, and the method further comprises the step of:
collecting one or more of the temperature and the humidity data from the data center through use of mobile measurement technology.

5. The method of claim 1, wherein the physical parameter data comprise air flow data, and the method further comprises the step of:
collecting the air flow data from the data center through use of one or more of a velometer flow hood and a vane anemometer.

6. The method of claim 1, wherein the metrics are adapted to quantify one or more of horizontal hotspots present in the data center, vertical hotspots present in the data center, non-targeted air flow present in the data center, sub-floor plenum hotspots present in the data center, air conditioning unit utilization in the data center and air conditioning unit air flow within the data center.

7. The method of claim 1, further comprising the step of:
repeating the making, collecting and compiling steps to assess the effectiveness of the recommendations, when implemented.

8. An apparatus for analyzing energy efficiency of a data center having a raised-floor cooling system with at least one air conditioning unit, the apparatus comprising:
a memory; and
at least one processor, coupled to the memory, operative to:
make an initial assessment of the energy efficiency of the data center based on one or more power consumption parameters of the data center;
compile physical parameter data obtained from one or more positions in the data center into one or more metrics if the initial assessment indicates that the data center is energy inefficient; and
make recommendations to increase the energy efficiency of the data center based on one or more of the metrics.

9. The apparatus of claim 8, wherein the cooling system further comprises at least one refrigeration chiller adapted to supply chilled water to the air conditioning unit, and the at least one processor is further operative to:
make an initial assessment of one or more of an air conditioning unit power consumption and a refrigeration chiller power consumption.

10. An article of manufacture for analyzing energy efficiency of a data center having a raised-floor cooling system with at least one air-conditioning unit, comprising a machine-readable medium containing one or more programs which when executed implement the steps of:
making an initial assessment of the energy efficiency of the data center based on one or more power consumption parameters of the data center;
compiling physical parameter data obtained from one or more positions in the data center into one or more metrics if the initial assessment indicates that the data center is energy inefficient; and
making recommendations to increase the energy efficiency of the data center based on one or more of the metrics.

11. The article of manufacture of claim 10, wherein the cooling system further comprises at least one refrigeration chiller adapted to supply chilled water to the air conditioning unit, and wherein the one or more programs when executed further implement the step of:
making an initial assessment of one or more of an air conditioning unit power consumption and a refrigeration chiller power consumption.

12. A method of providing a service for analyzing energy efficiency of a date center having a raised-floor cooling system with at least one air conditioning unit, the method comprising, the step of:
a service provider enabling the steps of:
making an initial assessment of the energy efficiency of the data center based on one or more power consumption parameters of the data center;
compiling physical parameter data obtained from one or more positions in the data center into one or more metrics if the initial assessment indicates that the data center is energy inefficient; and
making recommendations to increase the energy efficiency of the data center based on one or more of the metrics.
